(19) United States
(12) Patent Application Publication
(10) Pub. No.: US 2025/0379172 A1
(43) Pub. Date: Dec. 11, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: JAEEAN LEE, Suwon-si (KR); Dongwon Kang, Suwon-si (KR); Hongwon Kim, Suwon-si (KR); Changyeon Song, Suwon-si (KR)

(73) Assignee: Samsung Electronics Co., Ltd., Suwon-si (KR)

(21) Appl. No.: 19/088,408

(22) Filed: Mar. 24, 2025

(30) Foreign Application Priority Data
Jun. 5, 2024 (KR) 10-2024-0073632

(51) Int. Cl. H01L 23/00; H01L 21/48; H01L 21/56; H01L 23/498; H01L 23/538; H01L 25/03; H01L 25/18; H10B 80/00; H10D 80/30

(52) U.S. Cl. CPC H01L 24/26; H01L 21/4857; H01L 21/565; H01L 23/49894; H01L 23/5383; H01L 23/5386; H01L 23/562; H01L 24/16; H01L 24/27; H01L 24/32; H01L 24/73; H01L 25/03; H01L 24/08; H01L 25/18; H01L 2224/08225; H01L 2224/16227; H01L 2224/16238; H01L 2224/26175; H01L 2224/27013; H01L 2224/32225; H01L 2224/73204; H01L 2924/35; H10B 80/00; H10D 80/30

(57) ABSTRACT

A semiconductor package includes a substrate structure including: an inner substrate pad contacting a surface-mount semiconductor chip, and an outer substrate pad on an outer side of the inner substrate pad; a dam structure between the inner substrate pad and the outer substrate pad; and an underfill material layer including an underfill material filling an inside of the dam structure. The dam structure includes a plurality of dambars to reduce leakage of the underfill material in a direction from the inner substrate pad to the outer substrate pad, a plurality of connecting pads connecting the plurality of dambars to each other, a plurality of fixing pads in the substrate structure, and a plurality of fixing vias connecting the plurality of fixing pads and the plurality of connecting pads, respectively.

### CROSS-REFERENCE TO RELATED APPLICATION

This application claims the benefit of Korean Patent Application No. 10-2024-0073632, filed on Jun. 5, 2024, in the Korean Intellectual Property Office, the entire disclosure of which is incorporated herein by reference for all purposes.

### BACKGROUND

### 1. Field

Embodiments of the present disclosure relate to a semiconductor package and a method of manufacturing the same.

### 2. Description of Related Art

As electronic devices become lighter and higher performing, semiconductor packages also need to be miniaturized and higher performing. To implement miniaturized, light, high-performance, large-capacity, and high-reliability semiconductor packages, research and development on semiconductor packages with a structure in which semiconductor chips are stacked in multiple levels are continuously being conducted.

The above description is information the inventor(s) acquired during the course of conceiving the present disclosure, or already possessed at the time, and is not necessarily art publicly known before the present application was filed.

### SUMMARY

According to embodiments of the present disclosure, a semiconductor package for securing high reliability and a method of manufacturing the same are provided.

According to embodiments of the present disclosure, a miniaturized semiconductor package is provided.

According to embodiments of the present disclosure, a semiconductor package with a structure for saving manufacturing cost and time and a method of manufacturing the same are provided.

According to embodiments of the present disclosure, a semiconductor package may be provided and include: a substrate structure including an inner substrate pad physically contacting a surface-mount semiconductor chip, and an outer substrate pad on an outer side of the inner substrate pad; a dam structure between the inner substrate pad and the outer substrate pad; and an underfill material layer including an underfill material filling an inside of the dam structure. The dam structure includes: a plurality of dambars configured to reduce leakage of the underfill material in a direction from the inner substrate pad to the outer substrate pad; a plurality of connecting pads connecting the plurality of dambars to each other; a plurality of fixing pads in the substrate structure; and a plurality of fixing vias connecting the plurality of fixing pads and the plurality of connecting pads, respectively, and wherein a width of each dambar among the plurality of dambars is smaller than a width of each of a pair of fixing pads, among the plurality of fixing pads, closest to a corresponding dambar among the plurality of dambars.

According to embodiments of the present disclosure, a method of manufacturing a semiconductor package may be provided and include: forming an intermediate semiconductor package; forming, in the intermediate semiconductor package, a substrate structure including a dam structure, an inner substrate pad inside the dam structure, and an outer substrate pad outside of the dam structure; bonding a surface-mount semiconductor chip to the inner substrate pad; and filling an inside of the dam structure with an underfill material, wherein the dam structure includes: a plurality of dambars configured to reduce leakage of the underfill material to the outer substrate pad; a plurality of connecting pads connecting the plurality of dambars to each other; a plurality of fixing pads in the substrate structure; and a plurality of fixing vias connecting the plurality of fixing pads and the plurality of connecting pads, respectively, and wherein a width of each dambar among the plurality of dambars is smaller than a width of each of a pair of fixing pads, among the plurality of fixing pads, closest to a corresponding dambar among the plurality of dambars.

Additional aspects of embodiments will be set forth in part in the description which follows and, in part, will be apparent from the description, or may be learned by practice of the present disclosure.

According to embodiments of the present disclosure, it is possible to provide a dam structure in a semiconductor package, thereby reducing the issue of an underfill material interfering with surrounding components even when the underfill material is dispensed to a surface of a substrate structure including a material with high lubricity.

According to embodiments of the present disclosure, it is possible to form dambars of a dam structure to have a smaller width than another portion, thereby securing a sufficient margin of a keep-out zone (KOZ), which is a free space required so that an underfill material may not interfere with surrounding components when it is dispensed.

According to embodiments of the present disclosure, it is possible to apply a dam structure including dambars having a smaller width to a required KOZ margin, which is advantageous in miniaturizing a semiconductor package.

According to embodiments of the present disclosure, it is possible to form a dam structure simultaneously while forming a substrate pad, without the need to add a process of forming the dam structure, thereby saving cost and time for manufacturing a semiconductor package.

Effects achieved by the embodiments of the present disclosure are not limited to those described above, and other effects not mentioned above will be clearly derived and understood by one of ordinary skill in the art from the following description.

### BRIEF DESCRIPTION OF DRAWINGS

These and/or other aspects, features, and advantages of embodiments of the present disclosure will become apparent and more readily appreciated from the following description of example embodiments, taken in conjunction with the accompanying drawings of which:

FIG. 1 is a perspective view schematically illustrating a semiconductor package according to some embodiments of the present disclosure;

FIG. 2 is a cross-sectional view taken along a line I-I of FIG. 1;

FIG. 3 is a view illustrating a bottom surface of a semiconductor package according to some embodiments of the present disclosure;

FIG. 4 is a view in which a second semiconductor chip, an underfill material layer, and a package connection terminal are removed from FIG. 3;

FIG. 5A is an enlarged view of a portion D of FIG. 4;

FIG. 5B is a partial cross-sectional view taken along a line II-II of FIG. 5A;

FIG. 5C is a partial cross-sectional view taken along a line III-III of FIG. 5A;

FIG. 6A is a view illustrating a portion of a bottom surface of a semiconductor package according to some embodiments of the present disclosure;

FIG. 6B is a partial cross-sectional view taken along a line IV-IV of FIG. 6A;

FIG. 6C is a partial cross-sectional view taken along a line V-V of FIG. 6A;

FIG. 7A is a view illustrating a portion of a bottom surface of a semiconductor package according to a comparative example;

FIG. 7B is a partial cross-sectional view taken along a line VI-VI of FIG. 7A;

FIG. 7C is a partial cross-sectional view taken along a line VII-VII of FIG. 7A;

FIGS. 8A to 8E are views illustrating shapes of a dam structure according to some embodiments of the present disclosure;

FIGS. 9A and 9B are cross-sectional views of semiconductor packages according to some embodiments of the present disclosure;

FIG. 10 is a flowchart illustrating a semiconductor package manufacturing method according to some embodiments of the present disclosure;

FIG. 11A is a view illustrating a process of forming a half-finished semiconductor package according to some embodiments of the present disclosure;

FIG. 11B is a view illustrating a process of forming a first redistribution layer according to some embodiments of the present disclosure;

FIG. 11C is a view illustrating a process of forming a protective layer according to some embodiments of the present disclosure;

FIG. 11D is a view illustrating a process of forming a second redistribution layer according to some embodiments of the present disclosure;

FIG. 11E is a view illustrating a process of separating a substrate pad and a dam according to some embodiments of the present disclosure;

FIG. 11F is a view illustrating an underfill process according to some embodiments of the present disclosure; and

FIG. 12 is a diagram illustrating a configuration of an electronic device system including a semiconductor package according to some embodiments of the present disclosure.

### DETAILED DESCRIPTION

Hereinafter, non-limiting example embodiments will be described in detail with reference to the accompanying drawings. However, various alterations and modifications may be made to the example embodiments. Here, embodiments of the present disclosure are not meant to be limited by the descriptions of the present disclosure. The embodiments should be understood to include all changes, equivalents, and replacements within the spirit and scope of the present disclosure.

The terminology used herein is for the purpose of describing particular embodiments only and is not intended to be limiting. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing example embodiments of the present disclosure with reference to the accompanying drawings, like reference numerals refer to like components and a repeated description related thereto may be omitted. In the description of example embodiments, detailed description of well-known related structures or functions may be be omitted when it is deemed that such description will cause ambiguous interpretation of the present disclosure.

Also, in the description of the components, terms such as “first,” “second,” “A,” “B,” “(a),” “(b)” or the like may be used herein when describing components of embodiments of the present disclosure. These terms are used only for the purpose of distinguishing one component from another component, and the nature, the sequences, or the orders of the components are not limited by the terms. It should be noted that if one component is described as being “connected,” “coupled,” or “joined” to another component, the former may be directly “connected,” “coupled,” and “joined” to the latter or “connected,” “coupled,” and “joined” to the latter via another component.

A component, which has the same common function as a component included in any one embodiment, will be described by using the same name in other embodiments. Unless disclosed to the contrary, the configuration disclosed in any one embodiment may be applied to other embodiments, and the specific description of the repeated configuration may be omitted.

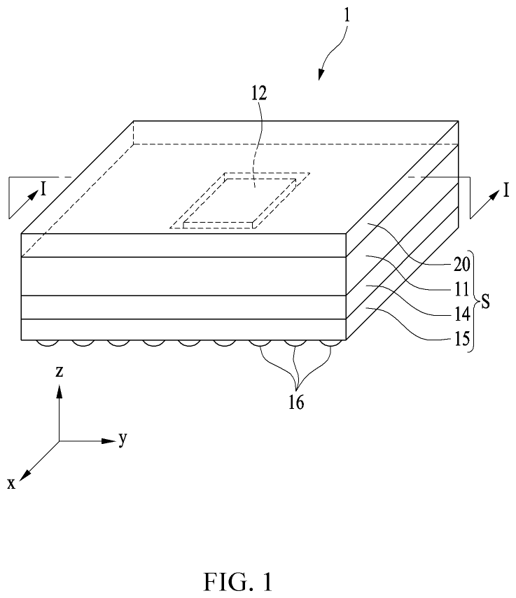

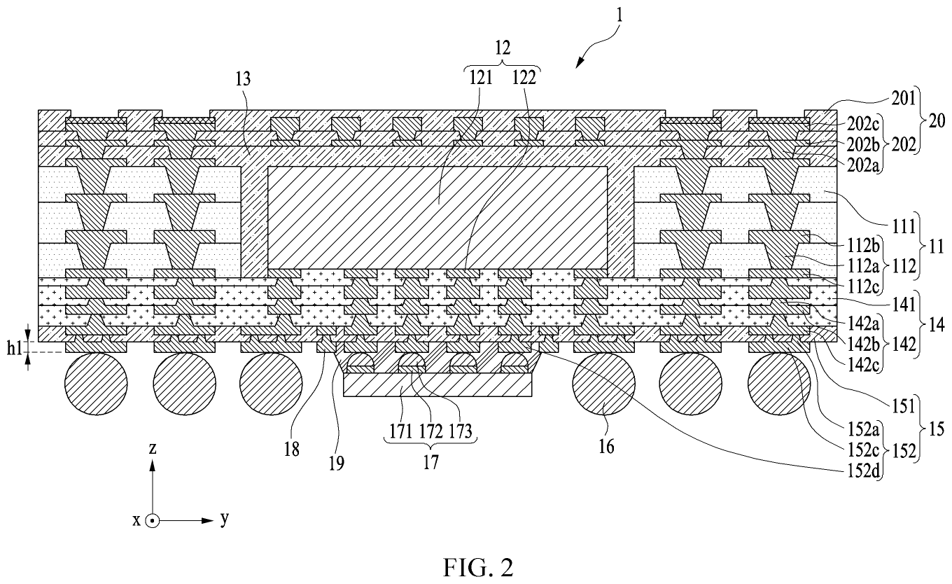

FIG. 1 is a perspective view schematically illustrating a semiconductor package according to some embodiments of the present disclosure, and FIG. 2 is a cross-sectional view taken along a line I-I of FIG. 1.

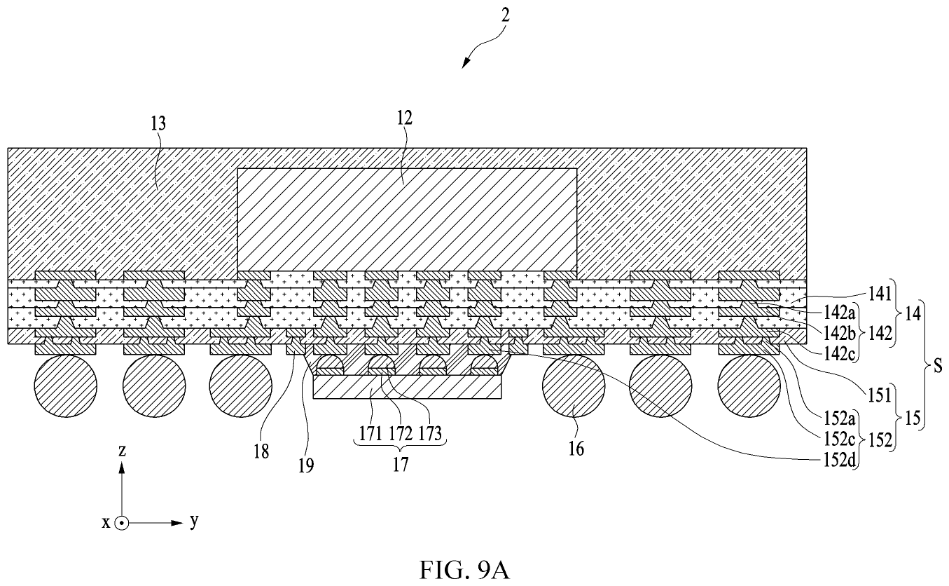

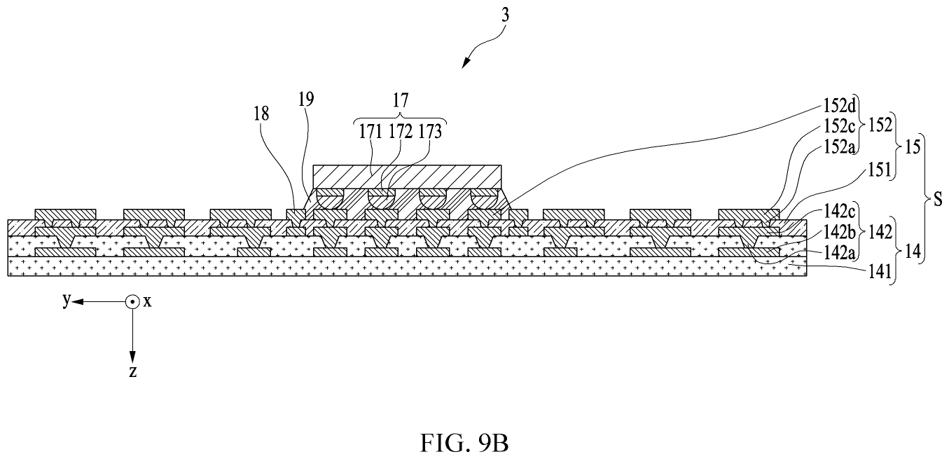

Referring to FIGS. 1 and 2, a semiconductor package 1 according to some embodiments may include a dam structure 18, as described later, thereby reducing the issue of an underfill material interfering with surrounding components even when the underfill material is dispensed to a surface of a substrate structure S (see FIGS. 9A-B) including a material with high lubricity.

FIGS. 1 and 2 exemplarily illustrate the semiconductor package 1 manufactured according to a fan-out panel level package (FOPLP) process. The semiconductor package 1 may include a core substrate 11, a first semiconductor chip 12, a molding layer 13, a first redistribution layer 14, a protective layer 15, an outer connection terminal 16, a second semiconductor chip 17, a dam structure 18, an underfill material layer 19, and a second redistribution layer 20. Hereinafter, description will be provided based on a semiconductor package manufactured according to the FOPLP process, but embodiments of the present disclosure are not necessarily limited thereto. Embodiments of the present disclosure in which some of the components described below are omitted should also be understood to be within the scope of the present disclosure.

The core substrate 11, the first redistribution layer 14, the protective layer 15, and the second redistribution layer 20 may be collectively referred to as a “substrate structure S.” Likewise, insulators (e.g., a core insulator 111, a first redistribution insulator 141, a protective layer insulator 151, and a second redistribution insulator 201) and wiring patterns (e.g., a core wiring pattern 112, a first redistribution pattern 142, a protective layer pattern 152, and a second redistribution pattern 202) provided on respective layers may be referred to as “substrate insulators” and “substrate wiring patterns.” Meanwhile, the substrate structure S may include only a portion of the layers described above. In other words, the substrate insulators and the substrate wiring patterns on respective layers may be formed of the same material and/or by the same process.

The core substrate 11 may include a cavity in which the first semiconductor chip 12 is mounted. The core substrate 11 may be formed by an embedded trace substrate (ETS) scheme. The core substrate 11 may include a core insulator 111 and a core wiring pattern 112.

The core insulator 111 may be formed of an insulating material, and provide a chip accommodation space in which the first semiconductor chip 12 is accommodated. The chip accommodation space may be formed by removing a partial area of the core insulator 111 to penetrate through the core insulator 111. For example, the process of forming the chip accommodation space may be performed through an etching process such as a drilling process, a laser ablation process, or laser cutting. For example, the core insulator 111 may include any one from among glass fiber, ceramic plate, epoxy, resin, and silicon oxide (SiO₂). Unless otherwise stated, the descriptions of the substrate insulators (e.g., the core insulator 111, the first redistribution insulator 141, the protective layer insulator 151, and the second redistribution insulator 201) can apply to each other.

The core wiring pattern 112 may be formed of a conductive material, and may at least partially penetrate through the core insulator 111 to be electrically connected to other adjacent components (e.g., the first semiconductor chip 12, the first redistribution layer 14, and/or the second redistribution layer 20). The core wiring pattern 112 may include a conductive material. For example, the core wiring pattern 112 may include at least one from among copper (Cu), aluminum (Al), silver (Ag), tin (Sn), gold (Au), nickel (Ni), lead (Pb), titanium (Ti), and alloys thereof, but is not limited thereto. Unless otherwise stated, the descriptions of the substrate wiring patterns (e.g., the core wiring pattern 112, the first redistribution pattern 142, the protective layer pattern 152, and the second redistribution pattern 202) can apply to each other. The core wiring pattern 112 may include a core via 112a penetrating through the core insulator 111 in the vertical direction, a core line 112b connected to the core via 112a and having a shape extending in the horizontal direction (e.g., the x-y plane direction) from the inside or surface of the core insulator 111, and a core pad 112c exposed to an outside of the core insulator 111 to be connected to other components. Meanwhile, a “line” and a “pad” may be formed on the same layer.

Meanwhile, FIGS. 1 and 2 illustrate the first semiconductor chip 12 embedded in the core substrate 11, but embodiments of the present disclosure are not limited thereto. For example, as shown in FIGS. 9A and 9B, the semiconductor package 1 may not include the core substrate 11 and/or the first semiconductor chip 12.

The first semiconductor chip 12 may be installed such that the protective layer 15 is between the first semiconductor chip 12 and the second semiconductor chip 17. For example, a portion of the first semiconductor chip 12 may be disposed in a position overlapping the second semiconductor chip 17 in the vertical direction, which may reduce the length of an electrical path between the first semiconductor chip 12 and the second semiconductor chip 17 and improve the electrical characteristics. When the core substrate 11 is formed by the ETS scheme, the first semiconductor chip 12 may be accommodated in the chip accommodation space formed in the core insulator 111. For example, the first semiconductor chip 12 may be a logic chip, a memory chip, or a bridge chip. The memory chip may be, for example, a volatile memory chip such as dynamic random access memory (DRAM) or static random access memory (SRAM), or a non-volatile memory chip such as phase-change random access memory (PRAM), magneto-resistive random access memory (MRAM), ferroelectric random access memory (FeRAM) or resistive random access memory (RRAM). The logic chip may be, for example, a central processing unit (CPU), a graphics processing unit (GPU), a microprocessor such as an application processor (AP), an analog element, or a digital signal processor. The first semiconductor chip 12 may include a first chip body 121 formed in a smaller volume than a volume of the chip accommodation space, and a first chip pad 122 formed on one surface of the first chip body 121 and connected to a first redistribution pattern 142 of the first redistribution layer 14.

The molding layer 13 may be formed of an insulating material, and fill the space between the core insulator 111 and the first semiconductor chip 12. For example, the molding layer 13 may be formed of a thermosetting resin such as an epoxy resin, a thermoplastic resin such as a polyimide resin, a resin having a reinforcing material such as an inorganic filler impregnated in the thermosetting resin and the thermoplastic resin, Ajinomoto Build-up Film (ABF), FR-4, Bismaleimide Triazine (BT), or an epoxy molding compound (EMC).

The first redistribution layer 14 may rearrange a pad already formed on a wafer to a desired position by additionally forming a metal layer on the pad. To rearrange the pad, the first redistribution layer 14 may be formed in a structure in which a plurality of layers are stacked through a plurality of (e.g., three) deposition processes as shown. For example, the first redistribution layer 14 may be formed to provide a fan-out structure for the first semiconductor chip 12, as described later. The first redistribution layer 14 may include a first redistribution insulator 141 and the first redistribution pattern 142.

The first redistribution insulator 141 may be formed of an insulating material. For example, the first redistribution insulator 141 may include an insulating polymer or a photosensitive insulating material (e.g., photo-imageable dielectric (PID)). For example, the photosensitive insulating material may include at least one from among photosensitive polyimide (PI), polybenzoxazole (PBO), phenol-based polymer, and benzocyclobutene-based polymer. For example, the first redistribution insulator 141 may be formed of a photosensitive insulating material (e.g., PID) to finely form the width of the first redistribution pattern 142.

The first redistribution pattern 142 may be formed of a conductive material, and may at least partially penetrate through the first redistribution insulator 141 to be electrically connected to other adjacent components (e.g., the core substrate 11, the first semiconductor chip 12, and/or the protective layer 15). For example, the first redistribution pattern 142 may be a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or alloys thereof, but is not limited thereto. In some embodiments, the first redistribution pattern 142 may be formed by stacking the metal or alloys mentioned above on a seed layer including copper, titanium, titanium nitride, or titanium tungsten. The first redistribution pattern 142 may include a first redistribution via 142a, a first redistribution line 142b, and a first redistribution pad 142c.

The first redistribution via 142a may at least partially penetrate through the first redistribution insulator 141 to be electrically connected to the first redistribution line 142b and/or the first redistribution pad 142c.

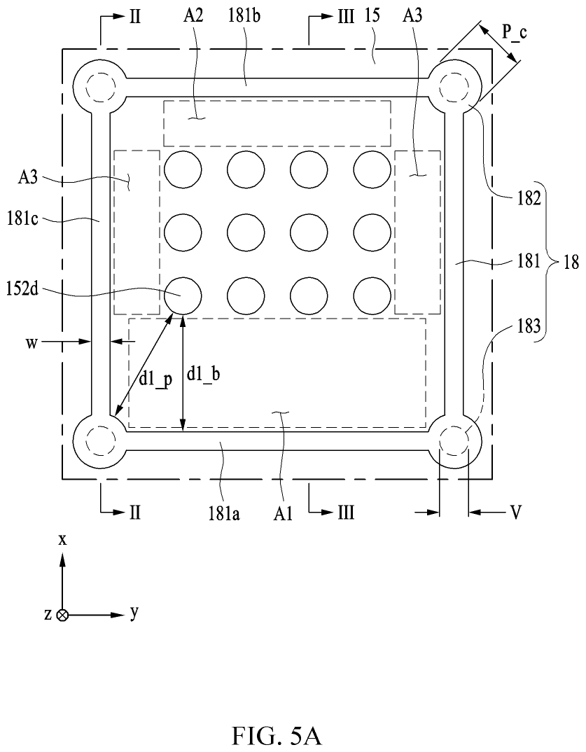

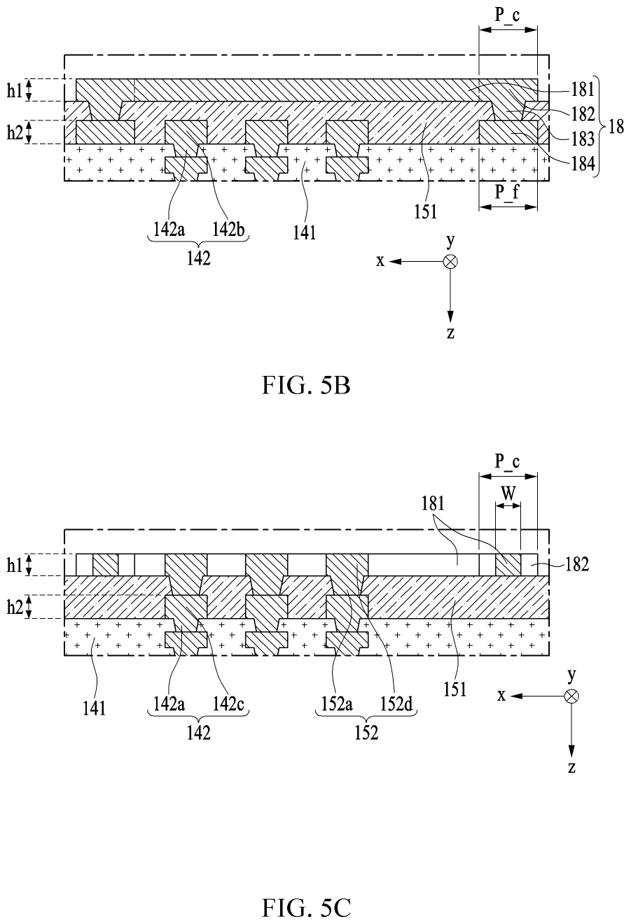

The first redistribution line 142b may be electrically connected to the first redistribution via 142a or the first redistribution pad 142c, and have a shape that extends in the horizontal direction (e.g., the x-y plane direction) from the inside or surface of the first redistribution insulator 141. For example, the first redistribution line 142b may protrude from the first redistribution insulator 141 and be positioned within a protective layer insulator 151, as described later with reference to FIG. 5B. In other words, the first redistribution line 142b may protrude toward the protective layer insulator 151 from an interface between the first redistribution insulator 141 and the protective layer insulator 151.

The first redistribution pad 142c may protrude from the first redistribution insulator 141 and be positioned within the protective layer insulator 151. In other words, the first redistribution pad 142c may protrude toward the protective layer insulator 151 from the interface between the first redistribution insulator 141 and the protective layer insulator 151.

The protective layer 15 may form the outermost layer of the substrate structure S. The protective layer 15 may be provided on the surface of the first redistribution layer 14 to cover the first redistribution layer 14. The protective layer 15 may be formed to prevent or reduce exposure of the first redistribution layer 14 to the outside and provide an electrical contact. For example, the protective layer 15 may be deposited a smaller number of times (e.g., once) than the number of depositions of the first redistribution layer 14. The protective layer 15 may include the protective layer insulator 151 and a protective layer pattern 152.

The protective layer insulator 151 may be formed of an insulating material. The protective layer insulator 151 may be formed of, for example, a material having higher heat resistance and/or lower hygroscopicity than the first redistribution insulator 141. The protective layer insulator 151 may include, for example, silicone, a polymer, a solid-state interlayer insulating film, or a photosensitive insulating material (e.g., PID). The polymer may be, for example, a polyimide or epoxy-based polymer.

For example, unlike a wafer-level package process, in the panel-level package process, it may be more advantageous to use a solid-state interlayer insulating film as the protective layer insulator 151. As an example, the solid-state interlayer insulating film may be an ABF film. On the other hand, since ABF has higher lubricity than PID, it may be beneficial to solve the issue of an underfill material overflowing when the underfill material is dispensed to the surface thereof. This issue may be reduced effectively through the dam structure 18.

The protective layer pattern 152 may be formed of a conductive material, and may at least partially penetrate through the protective layer insulator 151 to be electrically connected to other adjacent components (e.g., the first redistribution layer 14, the second semiconductor chip 17, and/or the outer connection terminal 16). The protective layer pattern 152 may include a protective layer via 152a, an outer substrate pad 152c, and an inner substrate pad 152d.

One side (e.g., a portion facing the −z direction of FIG. 2) of the protective layer via 152a may at least partially penetrate through the protective layer insulator 151 and be connected to the outer substrate pad 152c or the inner substrate pad 152d. The other side (e.g., a portion facing the +z direction of FIG. 2) of the protective layer via 152a may be connected to the first redistribution pad 142c. As a result, the first semiconductor chip 12 may be electrically connected to the inner substrate pad 152d and the outer substrate pad 152c through the first redistribution via 142a, the first redistribution pad 142c, and the protective layer via 152a.

The inner substrate pad 152d may be a portion positioned on an inner side of the dam structure 18, and may physically contact the second semiconductor chip 17. The inner substrate pad 152d may be electrically connected to another component (e.g., the first redistribution layer 14) through the protective layer pattern 152. The inner substrate pad 152d may be disposed at a position overlapping with the first semiconductor chip 12, when the semiconductor package 1 is viewed in the vertical direction (e.g., the z-axis direction). According to this structure, a short electrical transmission path may be provided compared to a case where the first semiconductor chip 12 and the second semiconductor chip 17 are connected in the horizontal direction, which may be advantageous in high performance and miniaturization. For example, all inner substrate pads 152d may overlap with the first semiconductor chip 12 and the second semiconductor chip 17, when the semiconductor package 1 is viewed in the vertical direction (e.g., the z-axis direction).

The outer substrate pad 152c may be a portion positioned on an outer side of the dam structure 18, and be connected to the outer connection terminal 16. At least a portion of the outer substrate pad 152c may be disposed at a position away from the first semiconductor chip 12, when the semiconductor package 1 is viewed in the vertical direction (e.g., the z-axis direction). According to this structure, it is possible to apply first semiconductor chips 12 in various sizes to the semiconductor package 1 through the configuration of the first redistribution layer 14 while maintaining the size of the semiconductor package 1 constant, which may be advantageous that the existing package test infrastructure can be used. In addition, it is possible to improve the input and output density of the first semiconductor chip 12, which may be advantageous in performance improvement, functional diversification, and system integration.

The outer substrate pad 152c and the inner substrate pad 152d may be formed to protrude from the protective layer insulator 151 as shown. For example, the outer substrate pad 152c and the inner substrate pad 152d may be formed simultaneously through a single plating process, and have the same protruding height h1 from the protective layer insulator 151.

The outer connection terminal 16 may be formed on the outer substrate pad 152c and may form physical and electrical connections with other components. For example, the outer connection terminal 16 may be provided in the form of a solder ball. The solder ball may include a solder material and may include, for example, tin, bismuth, lead, silver, or alloys thereof.

The second semiconductor chip 17 may be installed to physically contact the inner substrate pad 152d, and may be installed on the surface of the substrate structure S in a flip chip manner. Considering this structure, the second semiconductor chip 17 may be referred to as an “surface-mount semiconductor chip,” and the first semiconductor chip 12 may be referred to as an “additional semiconductor chip” to distinguish from the second semiconductor chip 17.

The second semiconductor chip 17 may include various types of passive components or various types of surface-mountable components. The second semiconductor chip 17 may be, for example, a multi-layer ceramic capacitor (MLCC), a low inductance chip capacitor (LICC), a land side capacitor (LSC), an inductor, an integrated passive device (IPD), or a silicon (Si) capacitor. The Si capacitor is a capacitor that is made using a silicon substrate and uses silicon oxide and nitride dielectric materials as dielectrics, and these materials may have several advantages in providing high reliability and stable capacitance with respect to heat and voltage. The second semiconductor chip 17 may include a second chip body 171, a second chip pad 172 formed on one surface of the second chip body 171, and an inner connection terminal 173 formed on the second chip pad 172. The inner connection terminal 173 may be a portion contacting the inner substrate pad 152d and may have, for example, a solder bump shape.

When the second chip pad 172 has a sufficiently large area, the second semiconductor chip 17 may be stably bonded to the inner substrate pad 152d even if a separate underfill material is not dispensed. Meanwhile, the Si capacitor may include multiple second chip pads 172 having a relatively small area compared to another semiconductor chip including an LSC, and may be bonded to the inner substrate pad 152d through a solder bump-type. This solder bump-type may involve an underfill process to ensure physical and electrical bond reliability.

The dam structure 18 may be installed between the inner substrate pad 152d and the outer substrate pad 152c, and may prevent leakage of an underfill material to the outside, irrespective of the lubricity of the surface to which the underfill material is dispensed during the process of performing the underfill process. An example structure of the dam structure 18 will be described later with reference to the drawings.

The underfill material layer 19 may be disposed inside the dam structure 18. The underfill material layer 19 may be formed by an underfill material filling the inside of the dam structure 18. The underfill material may include a polymeric material such as, for example, an epoxy resin formed by a capillary underfill method. The underfill material layer 19 may be formed between the protective layer insulator 151 and the second semiconductor chip 17. The underfill material layer 19 may be disposed to fill the gap between a plurality of the inner substrate pads 152d, and may connect the protective layer insulator 151 and the second semiconductor chip 17. The bonding force between the second semiconductor chip 17 and the inner substrate pad 152d may be improved through the underfill material layer 19.

The second redistribution layer 20 may be disposed on a side of the first redistribution layer 14 on which the first semiconductor chip 12 is disposed. This structure may utilize both sides of the substrate structure S, improving stacking efficiency. The second redistribution layer 20 may include a second redistribution insulator 201 and a second redistribution pattern 202.

The second redistribution insulator 201 may be formed of an insulating material. For example, as shown, the second redistribution insulator 201 may be formed of the same material (e.g., ABF) as the molding layer 13 or the protective layer 15, but embodiments of the present disclosure are not limited thereto.

The second redistribution pattern 202 may be formed of a conductive material, and may at least partially penetrate through the second redistribution insulator 201 and/or the molding layer 13 to be electrically connected to other adjacent components (e.g., the core substrate 11 and/or the first semiconductor chip 12). The second redistribution pattern 202 may include a second redistribution via 202a that at least partially penetrates the second redistribution insulator 201 to be electrically connected to the core wiring pattern 112, a second redistribution line 202b, and a second redistribution pad 202c that is electrically connected to the second redistribution via 202a and exposed to the outside of the second redistribution insulator 201. The surface of the second redistribution pad 202c may be plated with nickel (Ni) or gold (Au) to improve conductivity.

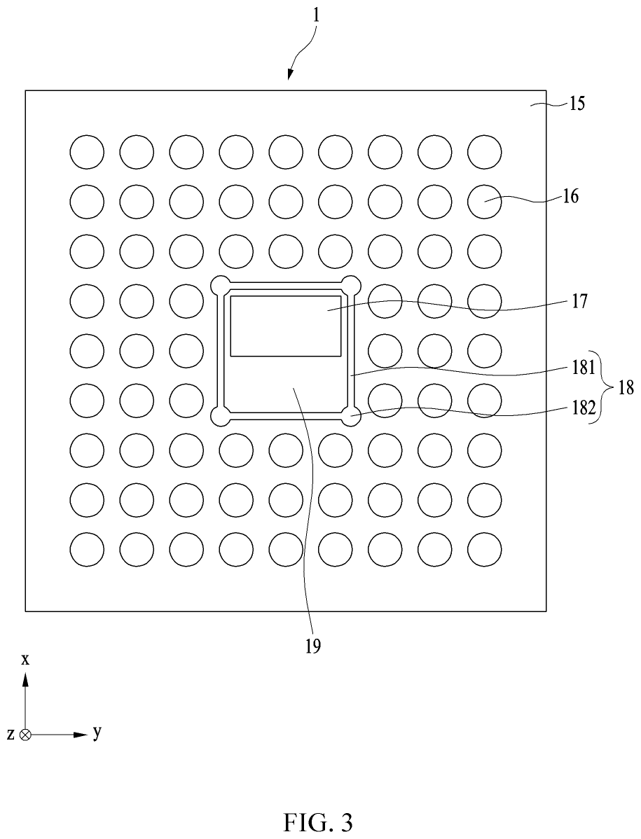

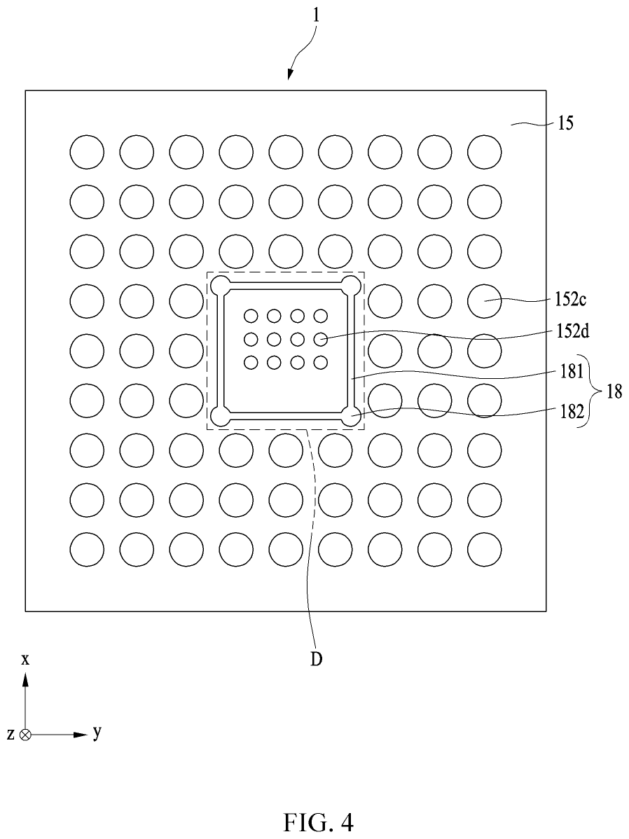

FIG. 3 is a view illustrating a bottom surface of a semiconductor package according to some embodiments of the present disclosure, and FIG. 4 is a view in which a second semiconductor chip, an underfill material layer, and a package connection terminal are removed from FIG. 3.

Referring to FIGS. 3 and 4, in the semiconductor package 1 according to some embodiments, the dam structure 18 may have a shape in which the inner substrate pad 152d is generally surrounded by a plurality of dambars 181 and a plurality of connecting pads 182 of the dam structure 18. For example, the dambars 181 and the connecting pads 182 may form a closed loop shape that surrounds the entire perimeter of the inner substrate pad 152d. This closed loop shape may reduce or prevent leakage of the underfill material filling the space between the second semiconductor chip 17 and the inner substrate pad 152d to the outside of the dam structure 18 such as, for example, the portion where the outer substrate pad 152c is formed. Meanwhile, the dam structure 18 does not necessarily have a closed loop shape.

When the dam structure 18 has a polygonal shape, the plurality of connecting pads 182 may be disposed at corner portions of the closed loop shape, and the plurality of dambars 181 may be disposed on straight portions of the closed loop shape. For example, the closed loop shape may be a rectangular shape as shown, and the plurality of connecting pads 182 may be arranged at the vertices of the rectangular shape, respectively. When the dam structure 18 is formed in a quadrangular shape, space efficiency for arranging each component (e.g., the semiconductor chip 17 having a quadrangular shape) of the semiconductor package 1 may improve. However, the closed loop shape described above is not necessarily limited to a quadrangular shape.

FIG. 5A is an enlarged view of a portion D of FIG. 4, FIG. 5B is a partial cross-sectional view taken along a line II-II of FIG. 5A, and FIG. 5C is a partial cross-sectional view taken along a line III-III of FIG. 5A.

Referring to FIGS. 5A to 5C, the dam structure 18 according to some embodiments may include the dambars 181, the connecting pads 182, fixing vias 183, and fixing pads 184.

The dambars 181 may reduce leakage of an underfill material from the inner substrate pad 152d to the outer substrate pad 152c during the process of forming the underfill material layer 19. The dambars 181 may include, as shown in FIG. 5A, a dispensing-side bar 181a having the longest shortest distance d1-b from the inner substrate pad 152d among the plurality of dambars 181, an exit-side bar 181b positioned on a side of the inner substrate pad 152d away from the dispensing-side bar 181a, and one or more side bars 181c positioned between the dispensing-side bar 181a and the exit-side bar 181b. In other words, the area surrounded by the dam structure 18 may include a dispensing area A1 defined as the space between the inner substrate pad 152d and the dispensing-side bar 181a, an exit area A2 defined as the space between the inner substrate pad 152d and the exit-side bar 181b, and a side area A3 positioned between the dispensing area A1 and the exit area A2, wherein, as shown, the width of the dispensing area A1 may be wider than the width of the exit area A2. In other words, the area where the inner substrate pad 152d is formed may be eccentrically disposed on one side of the area surrounded by the dambars 181. This structure may allow easier and more stable access to the dispensing area A1 which is relatively wide with a tool (e.g., a capillary nozzle) for performing an underfill process.

Meanwhile, a dambar 181 may be installed to be spaced apart from the fixing vias 183, as shown in FIG. 5B, and may be indirectly connected to the fixing vias 183 through the connecting pads 182. In other words, since the dambar 181 is not directly connected to the fixing vias 183, it is possible to determine the width w of the dambar 181 irrespective of the width V of the fixing vias 183 or the width P_f of the fixing pads 184, unlike a connecting pad 182 to be described later.

Therefore, by setting the width w of the dambar 181 to be smaller than the width P_c of the connecting pad 182 directly connected to the dambar 181, a margin of a KOZ for stably performing the underfill process may be additionally secured. For example, the margin of each of the dispensing area A1 and the exit area A2 may be increased by reducing the width w of each of the dispensing-side bar 181a and the exit-side bar 181b. Additionally, as much as the margin of the exit area A2 is increased, the inner substrate pad 152d may be arranged more eccentrically toward the exit area A2. For example, when the width w of the dambar 181 is halved, the margin of the dispensing area A1 may increase by twice the reduced width. Conversely, it is possible to miniaturize the dam structure 18 while maintaining the same margins, the structure described above has the advantage of miniaturizing the whole semiconductor package 1.

For example, the width w of each dambar 181 may be smaller than the width P_c of each of a pair of connecting pads 182 directly connected to the corresponding one of the dambars 181. For example, the width w of each dambar 181 may be set to be smaller than the width P_f of each of a pair of fixing pads 184 closest to the corresponding one of the dambars 181. Furthermore, the width w of a dambar 181 closest to one fixing via 183 among the plurality of dambars 181 may be smaller than the smaller value between the width P_c of a connecting pad 182 directly connected to the one fixing via 183 and the width P_f of a fixing pad 184 directly connected to the one fixing via 183. For example, the width w of all dambars 181 may be smaller than the width P_c of all connecting pads 182. For example, the width w of all dambars 181 may be smaller than the width P_f of all fixing pads 184.

For example, the width w of each dambar 181 may be equal to or smaller than ½ of the width P_c of each of a pair of connecting pads 182 closest to the corresponding one of the dambars 181. For example, the width w of each dambar 181 may be equal to or smaller than ½ of the width P_f of each of a pair of fixing pads 184 closest to the corresponding one of the dambars 181.

For example, the width w of each dambar 181 may also be set to be equal to or smaller than the width V of a fixing via 183 closest to the corresponding dambar 181.

Meanwhile, according to the structure described above, the fixing vias 183 are not positioned under the dambar 181, and thus, a free volume to form a wiring pattern additionally to the portion of the protective layer insulator 151 under the dambar 181 may be provided. For example, as shown in FIG. 5B, the first redistribution line 142b may protrude from the first redistribution insulator 141 and be positioned within the protective layer insulator 151. In this case, the first redistribution line 142b positioned within the protective layer insulator 151 may be arranged in a shape that traverses at least a portion of the plurality of dambars 181, when viewed in a direction (e.g., the z-axis direction) parallel to the depth direction of the first redistribution via 142a. This structure may improve the degree of freedom in configuring the first redistribution pattern 142.

A connecting pad 182 may connect a plurality of dambars 181 to each other. For example, the center of the connecting pad 182 may be positioned at a portion where the center lines of a pair of dambars 181 adjacent thereto intersect. The width P_c of the connecting pad 182 may be larger than the width V of a fixing via 183 directly connected to the connecting pad 182. The connecting pad 182 may have a width P_c that is larger than the width V of the fixing via 183, so as to completely overlap with the fixing via 183 when viewed in the depth direction (e.g., the z-axis direction) of the fixing via 183. Such a width configuration may be set in consideration of alignment and machining tolerance during the manufacturing process, and through these configuration conditions, the connecting pad 182 may be stably connected to the fixing via 183.

Meanwhile, as shown in FIG. 5A, the shortest distance d1_p from each of a pair of connecting pads 182, directly connected to the dispensing-side bar 181a, to the inner substrate pad 152d may be formed to be longer than the shortest distance d1_b from the dispensing-side bar 181a to the inner substrate pad 152d. Since this structure may reduce the negative effect of the width P_c of the connecting pad 182 on securing the underfill KOZ margin, it is possible to configure the underfill KOZ margin based on the dispensing-side bar 181a, without considering the connecting pad 182.

A fixing via 183 may connect a connecting pad 182 and a fixing pad 184 to each other. The width V of a fixing via 183 may be smaller than the width P_f of a fixing pad 184 directly connected to the fixing via 183.

This structure may prevent the dam structure 18 from being delaminated from the substrate structure S while the fixing pad 184 is embedded in the substrate structure S. For example, the width P_f of the fixing pad 184 may be formed to be larger than the width P_c of the connecting pad 182 to secure a stable fixing force.

Meanwhile, as shown in FIGS. 5B and 5C, the fixing pad 184 may be installed to be spaced apart from the first redistribution via 142a, and the first redistribution pad 142c and the plurality of fixing pads 184 may have the same protruding height h2 from the first redistribution insulator 141. According to this structure, it is possible to simultaneously form the first redistribution pad 142c and the fixing pad 184 during the process of forming the first redistribution pad 142c.

Likewise, the dam structure 18 including the fixing pad 184 may be formed simultaneously during the process of forming a wiring pattern in the substrate structure S. According to these process characteristics, the plurality of dambars 181, the plurality of connecting pads 182, the outer substrate pads 152c (see FIG. 1), and the inner substrate pads 152d may have the same protruding height h1 from the protective layer insulator 151.

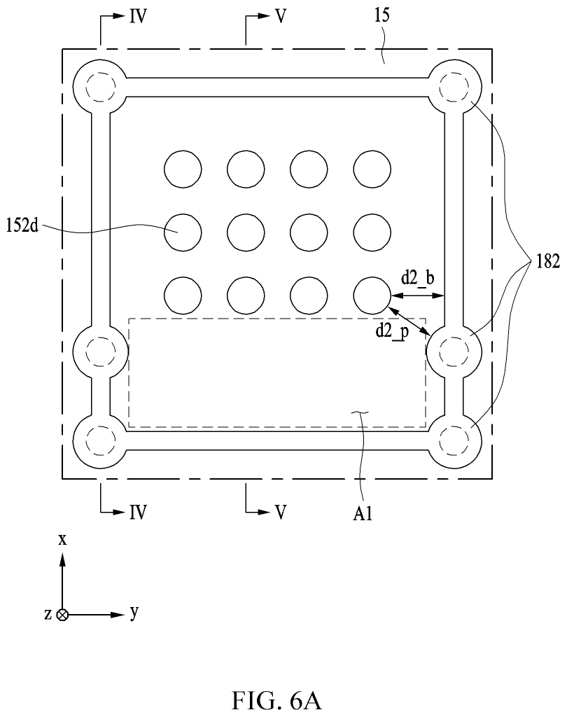

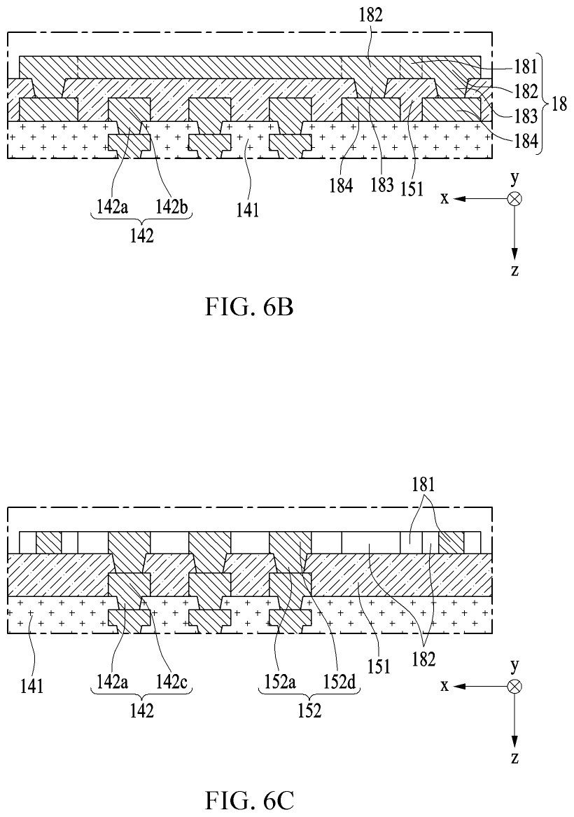

FIG. 6A is a view illustrating a portion of a bottom surface of a semiconductor package according to some embodiments of the present disclosure, FIG. 6B is a partial cross-sectional view taken along a line IV-IV of FIG. 6A, and FIG. 6C is a partial cross-sectional view taken along a line V-V of FIG. 6A.

Referring to FIGS. 6A to 6C, connecting pads 182, fixing vias 183, and fixing pads 184 according to some embodiments may be additionally installed in straight portions, rather than just the corner portions, of the closed loop shape of the dam structure 18. This structure may further reduce the possibility of delamination of the dambars 181 from the substrate structure S.

Meanwhile, in this case, there is a possibility of reducing the underfill KOZ margin compared to the embodiment shown in FIGS. 5A to 5C. To reduce the negative effect on the underfill KOZ margin, the shortest distance d2_p from each connecting pad 182 to the inner substrate pad 152d may be formed to be longer than the shortest distance d2_b from each of a pair of dambars 181 directly connected to the corresponding connecting pad 182 to the inner substrate pad 152d. Meanwhile, the configuration conditions described above may identically apply to the connecting pads 182 installed in the corner portions.

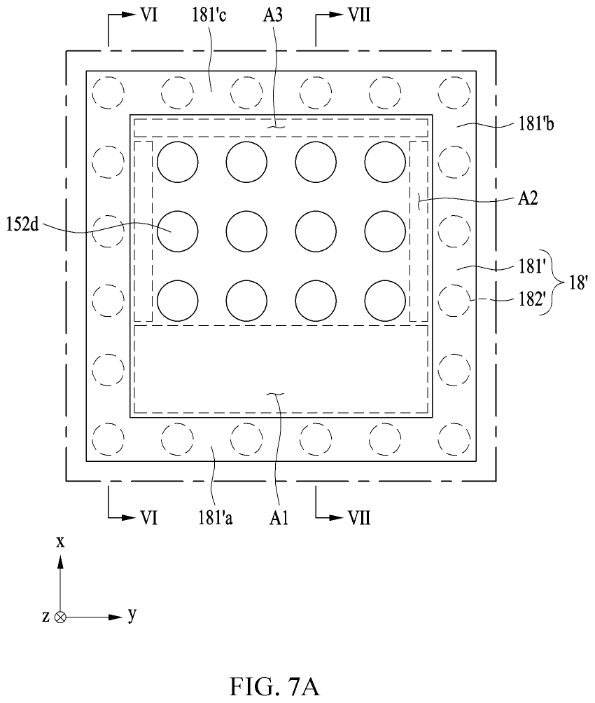

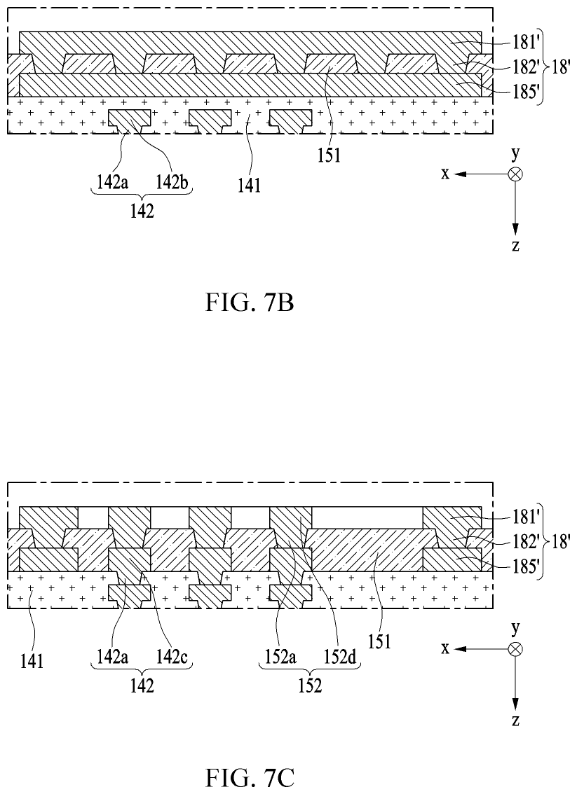

FIG. 7A is a view illustrating a portion of a bottom surface of a semiconductor package according to a comparative example, FIG. 7B is a partial cross-sectional view taken along a line VI-VI of FIG. 7A, and FIG. 7C is a partial cross-sectional view taken along a line VII-VII of FIG. 7A.

Referring to FIGS. 7A to 7C, a dam structure 18′ according to the comparative example may include a dambar 181′, fixing vias 182′, and a fixing line 185′. According to the comparative example, separate connecting pads or fixing pads are not provided, and the fixing line 185′ corresponding to the shape (e.g., square shape) of the dambar 181′ has the same shape (e.g., square shape) as the overall shape of the dambar 181′ and is embedded in the protective layer insulator 151. Additionally, the dambar 181′ is directly connected to the fixing via 182′. According to this structure, it may be confirmed that the overall thickness of the dambar 181′ needs to be larger than the width of the fixing via 182′. As a result, it may be confirmed that the dispensing area A1, the exit area A2, and the side area A3 are inevitably formed relatively narrow and that it is difficult to secure a sufficient underfill KOZ margin as in the embodiment described above. In addition, it may also be confirmed that it is difficult to provide a free volume to form an additional wiring pattern under the dambar 181′.

It may be seen that a sufficiently wide underfill KOZ margin may be secured according to the embodiments of the present disclosure, compared to the comparative example. Also, on the contrary, it may be confirmed that the area occupied by the dam structure 18 may be reduced under the same underfill KOZ margin conditions and, thus, the whole semiconductor package may be miniaturized.

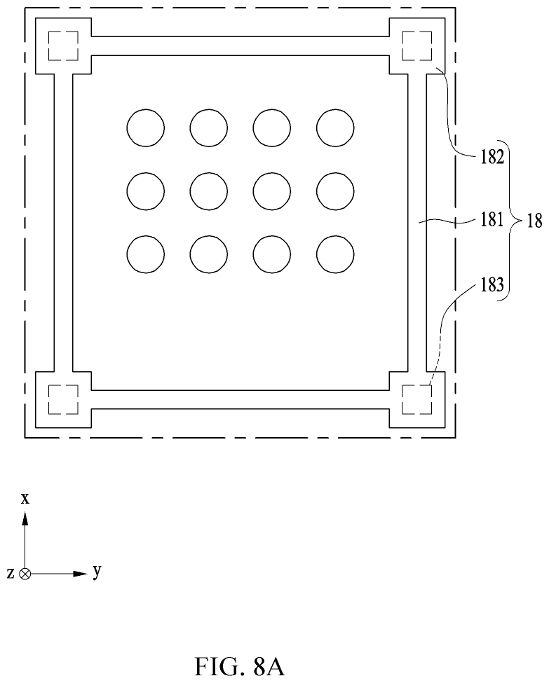

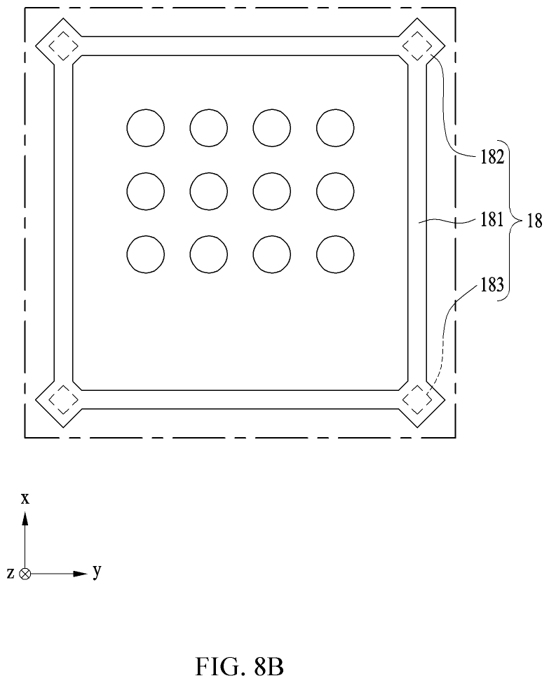

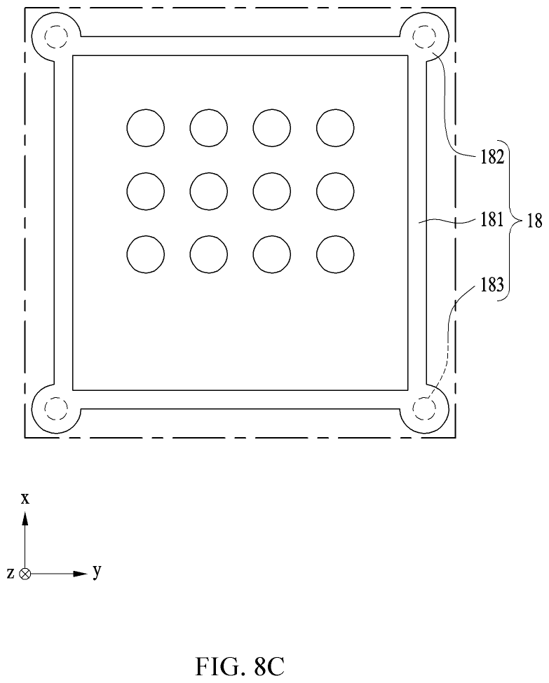

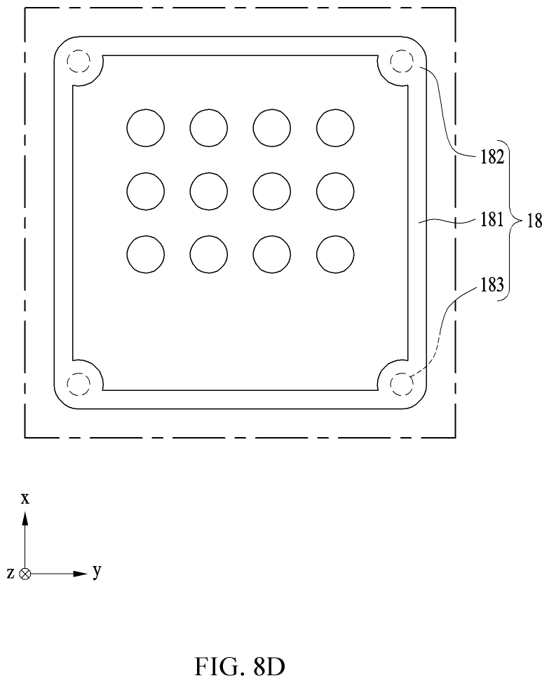

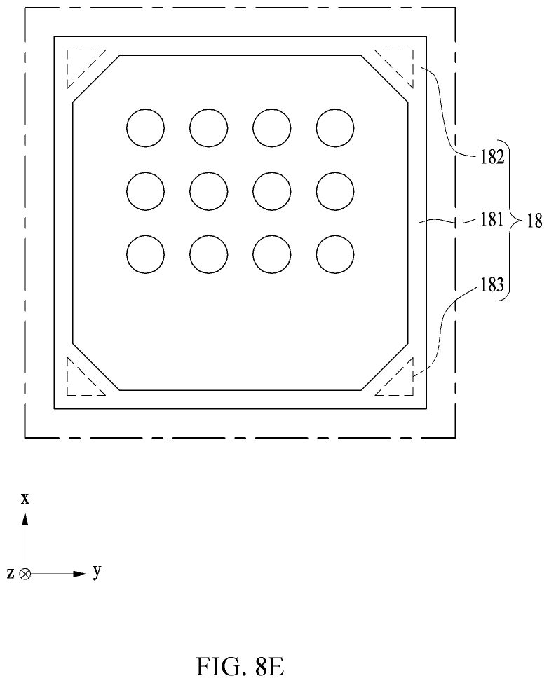

FIGS. 8A to 8E are views illustrating shapes of a dam structure according to some embodiments of the present disclosure.

Referring to FIGS. 8A to 8E, various example shapes of connecting pads 182 and/or fixing vias 183 and their relative arrangement relationships with a dambar 181 according to some embodiments may be confirmed.

The connecting pads 182 and/or the fixing vias 183 may be formed in a circular shape as in the embodiments described above, and may also be formed in a polygonal shape (e.g., a square, diamond, or triangular shape) as shown in FIGS. 8A to 8E.

For example, as shown in FIG. 8C, the center of a connecting pad 182 may be positioned on an outer side of a portion where virtual centerlines passing through the centers of a pair of dambars 181 adjacent thereto intersect. For example, the connecting pads 182 may not be positioned in an inner space surrounded by the dambar 181. This shape may reduce or eliminate the proportion of the connecting pads 182 occupying the inner space of the dam structure 18 and, thus, further improve the underfill KOZ margin.

Meanwhile, as shown in FIGS. 8D and 8E, the center of a connecting pad 182 may be positioned on an inner side of where virtual centerlines passing through the centers of a pair of dambars 181 adjacent thereto intersect. For example, the connecting pads 182 may be arranged in positions not protruding outward from the dambars 181. This shape may reduce or eliminate the proportion of the connecting pads 182 occupying the outer space of the dam structure 18 and, thus, reduce the issue of causing interference with the components positioned outside the dam structure 18 during the manufacturing process.

FIGS. 9A and 9B are cross-sectional views of semiconductor packages according to some embodiments of the present disclosure.

FIG. 9A illustrates a semiconductor package 2 having a fan-out-type flip chip structure. The semiconductor package 2 according to some embodiments may include a first semiconductor chip 12, a molding layer 13, a first redistribution layer 14, a protective layer 15, an outer connection terminal 16, a second semiconductor chip 17, a dam structure 18, and an underfill material layer 19. The first redistribution layer 14, the protective layer 15, and the second redistribution layer 20 may be collectively referred to as a “substrate structure S.” Likewise, insulators (e.g., a first redistribution insulator 141, a protective layer insulator 151, and a second redistribution insulator 201) and wiring patterns (e.g., a first redistribution pattern 142, a protective layer pattern 152, and a second redistribution pattern 202) provided on respective layers may be referred to as “substrate insulators” and “substrate wiring patterns.” Meanwhile, the substrate structure S may include only a portion of the layers described above.

FIG. 9B illustrates a semiconductor package 3 having a flip chip structure. The semiconductor package 3 according to some embodiments may include a first redistribution layer 14, a protective layer 15, a surface-mount semiconductor chip (e.g., the second semiconductor chip 17), a dam structure 18, and an underfill material layer 19. The first redistribution layer 14 and the protective layer 15 may be collectively referred to as a “substrate structure S.” Likewise, insulators (e.g., a first redistribution insulator 141 and a protective layer insulator 151) and wiring patterns (e.g., a first redistribution pattern 142 and a protective layer pattern 152) provided on respective layers may be referred to as “substrate insulators” and “substrate wiring patterns.” Meanwhile, the substrate structure S may include only a portion of the layers described above.

The substrate wiring patterns (e.g., the first redistribution pattern 142 and the protective layer pattern 152) may electrically connect the outer substrate pad 152c and the inner substrate pad 152d to each other.

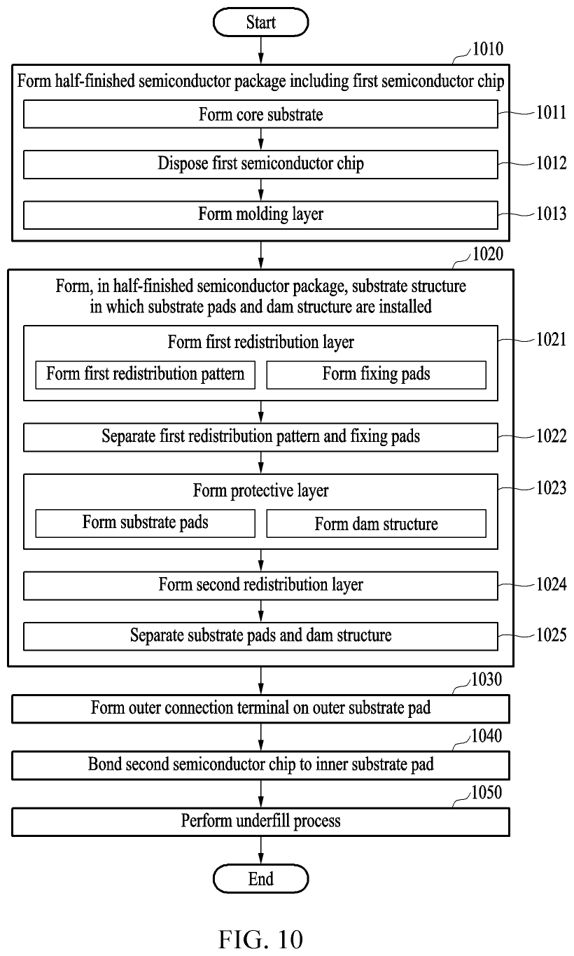

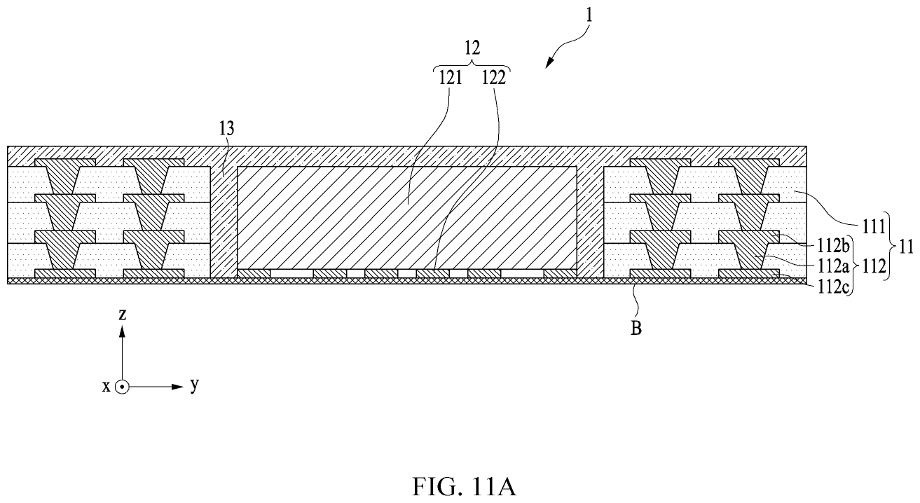

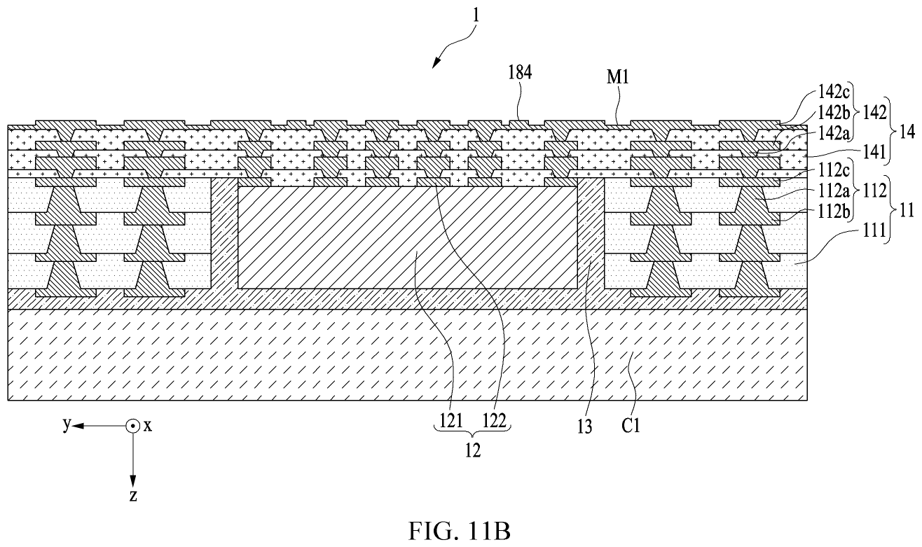

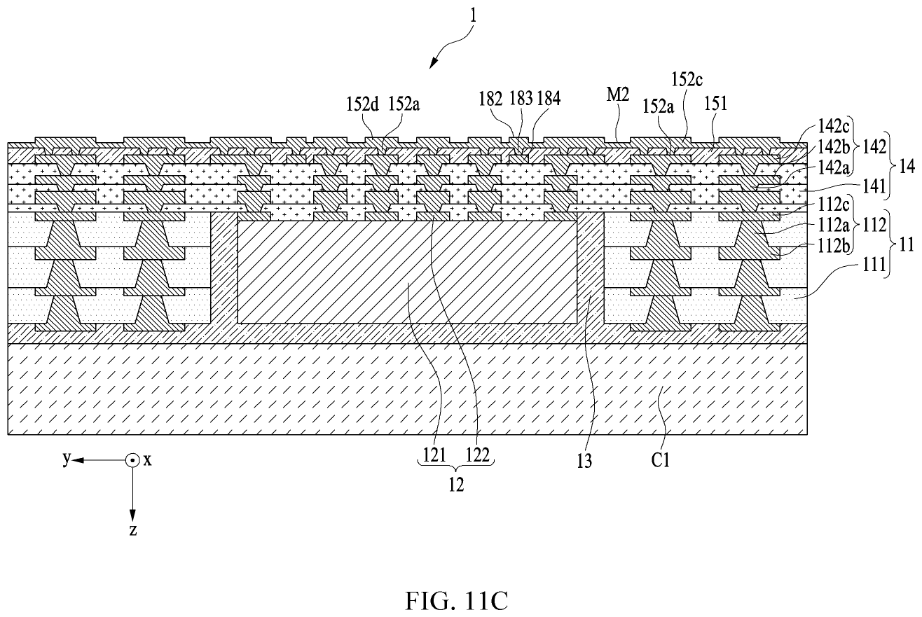

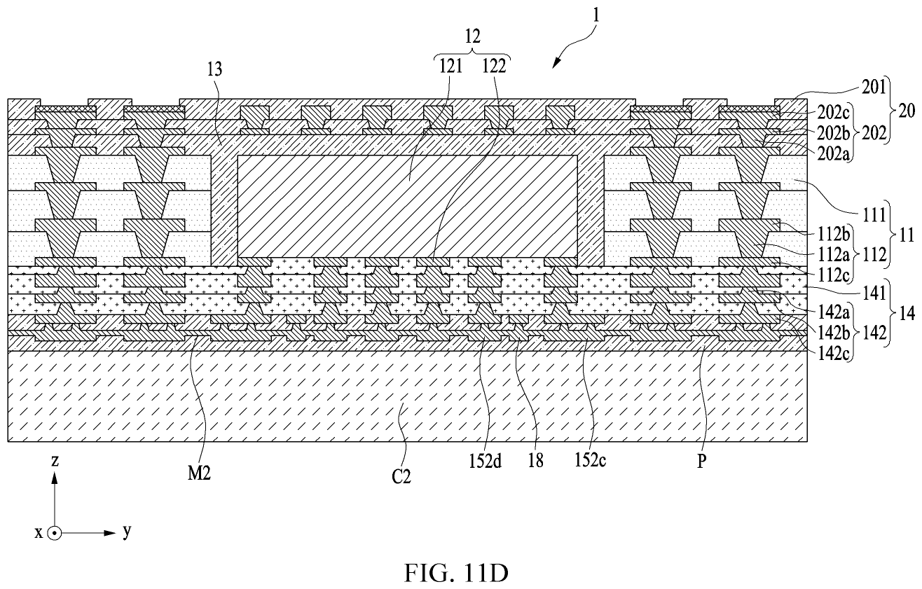

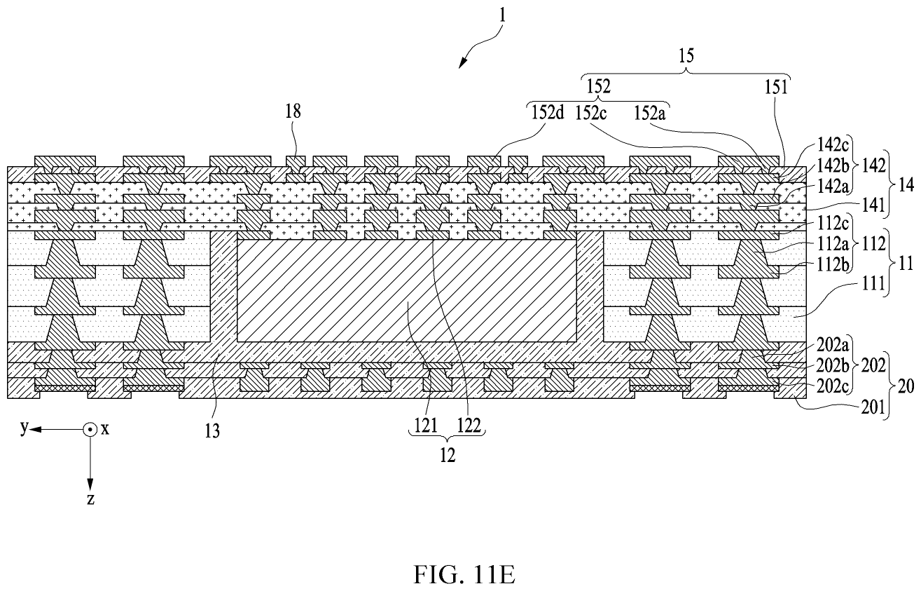

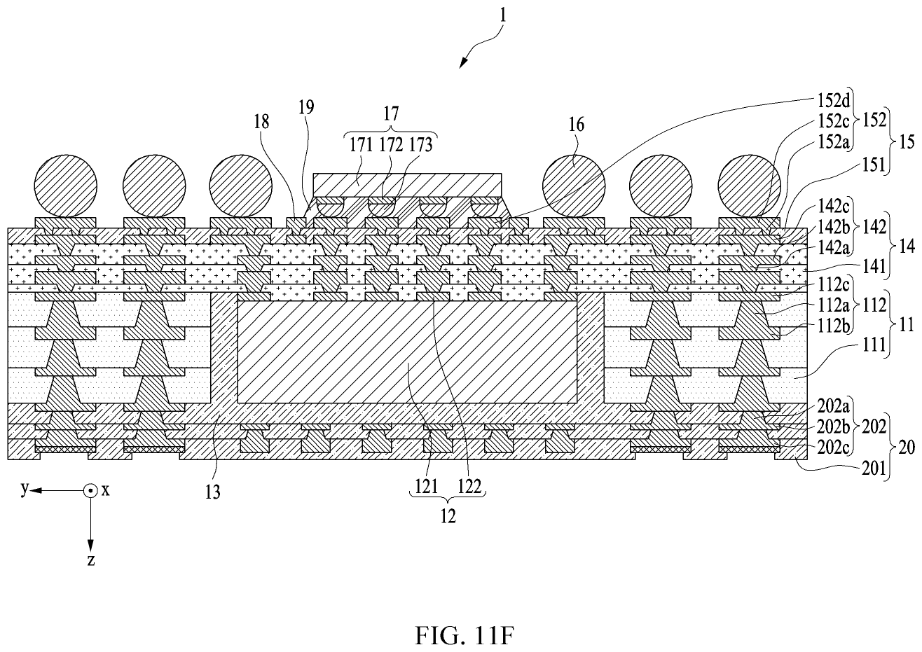

FIG. 10 is a flowchart illustrating a semiconductor package manufacturing method according to some embodiments of the present disclosure, and FIGS. 11A to 11F are views illustrating some of processes of the semiconductor package manufacturing method according to some embodiments of the present disclosure. FIGS. 11A to 11F may be understood as the cross sections at the same position as FIG. 2.

Referring to FIGS. 10 to 11F, a semiconductor package manufacturing method according to some embodiments may include a process 1010 of forming a half-finished (e.g., an intermediate) semiconductor package, a process 1020 of forming, in the half-finished semiconductor package, a substrate structure S in which substrate pads (e.g., outer substrate pads 152c and inner substrate pads 152d) and a dam structure 18 are installed, a process 1030 of forming outer connection terminals 16 on the outer substrate pads 152c, a process 1040 of bonding a surface-mount semiconductor chip (e.g., the second semiconductor chip 17) to the inner substrate pads 152d, and a process 1050 of filling the inside of the dam structure 18 with an underfill material. Unless otherwise stated, the order of the processes described in the present disclosure is not limited, and some of the processes may be performed reversely or simultaneously. For example, the process 1030 may be performed after the process 1040 and the process 1050.

Referring to FIG. 10, the process 1010 of forming a half-finished semiconductor package may include a process 1011 of forming a core substrate 11, a process 1012 of disposing an additional semiconductor chip (e.g., the first semiconductor chip 12) in a chip accommodation space, and a process 1013 of forming a molding layer 13 by filling the space between a core insulator 111 and the additional semiconductor chip (e.g., the first semiconductor chip 12).

Referring to FIG. 11A, the processes 1011 to 1013 may be performed on a temporary adhesive layer B. A half-finished (e.g., intermediate) semiconductor package as shown in FIG. 11A may be formed by forming the molding layer 13 in a state in which the core substrate 11 and the first semiconductor chip 12 are attached to the temporary adhesive layer B. Here, the temporary adhesive layer B is temporarily used to form the molding layer 13 and may be removed before or during the process described later.

Meanwhile, an example in which the half-finished (e.g., intermediate) semiconductor package includes an ETS is described with reference to FIG. 11A, but the half-finished semiconductor package does not necessarily include a ETS. As an example, the half-finished semiconductor package may be configured in a form in which the additional semiconductor chip (e.g., the first semiconductor chip 12) and the molding layer 13 described with reference to FIG. 9A are attached to the temporary adhesive layer B. As another example, the half-finished semiconductor package may be a base layer (e.g., an insulator including a silicon material) of the substrate structure S described with reference to FIG. 9B. In other words, the half-finished (e.g. intermediate) semiconductor package may be any part that may be generated during the process of manufacturing a semiconductor package.

Referring to FIG. 10, the process 1020 of forming a substrate structure S may include a process 1021 of forming a first redistribution layer 14 on the half-finished semiconductor package and a process 1022 of separating a plurality of fixing pads 184 from a wiring pattern of the substrate structure S.

Referring to FIG. 11B, to perform the process 1021, the half-finished semiconductor package may be reversed (e.g., flipped) upside down while a first carrier C1 is attached to the molding layer 13, and the temporary adhesive layer B described above may be removed.

The process 1021 may include, for example, (a) a process of forming a first redistribution insulator 141, (b) a process of depositing a first redistribution metal film M1 on the first redistribution insulator 141, (c) a process of depositing, on the first redistribution metal film M1, a first redistribution mask including (i) holes to form first redistribution pads 142c and (ii) holes to form a plurality of fixing pads 184, and (d) a first plating process of forming the first redistribution pads 142c and the plurality of fixing pads 184 simultaneously by plating the first redistribution metal film M1 in a state in which the first redistribution mask is disposed.

As described above, the first redistribution pads 142c and the plurality of fixing pads 184 may be formed through the same first plating process. Finally, the first redistribution pads 142c and the fixing pads 184 may have the same height h2 with respect to the first redistribution insulator 141, as described above with reference to FIGS. 5B and 5C.

Meanwhile, when the first plating process is completed, the first redistribution pads 142c and the fixing pads 184 may be connected to each other by the first redistribution metal film M1. Accordingly, after the first plating process is performed, the first redistribution metal film M1 may be etched in the process 1022, such that the plurality of fixing pads 184 may be separated from the wiring pattern (e.g., the first redistribution pad 142c) of the substrate structure S.

Referring to FIG. 10, the process 1020 of forming a substrate structure S may include a process 1023 of forming a protective layer 15 on the first redistribution layer 14 and a process 1025 of separating the dam structure 18 from the wiring pattern of the substrate structure S.

Referring to FIG. 11C, the process 1023 may include (a) a process of forming a protective layer insulator 151 including (i) holes to form protective layer vias 152a electrically connected to the first redistribution pads 142c and (ii) holes to form a plurality of fixing vias 183, (b) a process of depositing a protective layer metal film M2 on the protective layer insulator 151, (c) a process of disposing, on the protective layer metal film M2, a protective layer mask including (i) holes to form outer substrate pads 152c, (ii) holes to form inner substrate pads 152d, (iii) holes to form a plurality of dambars 181, and (iv) holes to form a plurality of connecting pads 182, and (d) a second plating process of forming the protective layer vias 152a, the plurality of fixing vias 183, the outer substrate pads 152c, the inner substrate pads 152d, the plurality of dambars 181, and the plurality of connecting pads 182 simultaneously by plating the protective layer metal film M2 in a state in which the protective layer mask is disposed.

As described above, the protective layer vias 152a, the plurality of fixing vias 183, the outer substrate pads 152c, the inner substrate pads 152d, the plurality of dambars 181, and the plurality of connecting pads 182 may be formed through the same second plating process. Finally, the outer substrate pads 152c, the inner substrate pads 152d, the plurality of dambars 181, and the plurality of connecting pads 182 may have the same height h1 with respect to the protective layer insulator 151, as described above with reference to FIGS. 5B and 5C.

Meanwhile, when the second plating process is completed, the protective layer vias 152a, the plurality of fixing vias 183, the outer substrate pads 152c, the inner substrate pads 152d, the plurality of dambars 181, and the plurality of connecting pads 182 may be connected to each other by the protective layer metal film M2. Accordingly, after the second plating process is performed, the protective layer metal film M2 may be etched in the process 1025, such that the dam structure 18 may be separated from the wiring pattern (e.g., the outer substrate pads 152c and the inner substrate pads 152d) of the substrate structure S.

Referring to FIG. 10, the process 1020 of forming a substrate structure S may include a process 1024 of forming a second redistribution layer 20 on a side of the first redistribution layer 14 on which the additional semiconductor chip (e.g., the first semiconductor chip 12) is provided.

Referring to FIG. 11D, the process 1024 may include (a) a process of forming a temporary protective layer P on the surfaces of the protective layer metal film M2, the outer substrate pads 152c, the inner substrate pads 152d, and the dam structure 18, (b) a process of reversing the half-finished semiconductor package upside down in a state in which a second carrier C2 is attached to the temporary protective layer P, (c) a process of forming, on the opposite side of the temporary protective layer P, a second redistribution insulator 201 and a second redistribution pattern 202 that at least partially penetrates the second redistribution insulator 201 and is electrically connected to a core wiring pattern 112, and (d) a process of removing the temporary protective layer P so that the surface of each of the protective layer metal film M2, the outer substrate pads 152c, the inner substrate pads 152d, and the dam structure 18 is exposed to the outside.

Here, the temporary protective layer P may be temporarily formed for attaching the second carrier C2 and removed at the last stage of the process 1024. Meanwhile, it may be beneficial to ensure that the first redistribution layer 14 is not removed while removing the temporary protective layer P. For example, the temporary protective layer P may be removed through laser processing and, in this case, a metal film may be covered on the first redistribution layer 14 and used as a laser stopper.

Meanwhile, if the process 1025 of etching the protective layer metal film M2 is performed after the process of removing the temporary protective layer P as shown, the protective layer metal film M2 may be used as a laser stopper as described above as well as a seed layer for plating.

When the process 1024 of forming a second redistribution layer 20 is added to process 1020 of forming a substrate structure S as described above, the process 1025 of etching the protective layer metal film M2 may be performed after the second redistribution layer 20 is formed.

Referring to FIG. 11E, the dam structure 18 separated from the wiring pattern (e.g., the outer substrate pads 152c and the inner substrate pads 152d) of the substrate structure S by etching the protective layer metal film M2 after removing the temporary protective layer P is shown. By etching the protective layer metal film M2 in the process 1025 as described above, the outer substrate pads 152c, the inner substrate pads 152d, and the dam structure 18 may be physically separated from each other.

Thereafter, by performing the processes 1030, 1040, and 1050, a semiconductor package 1 as shown in FIG. 11F may be completed.

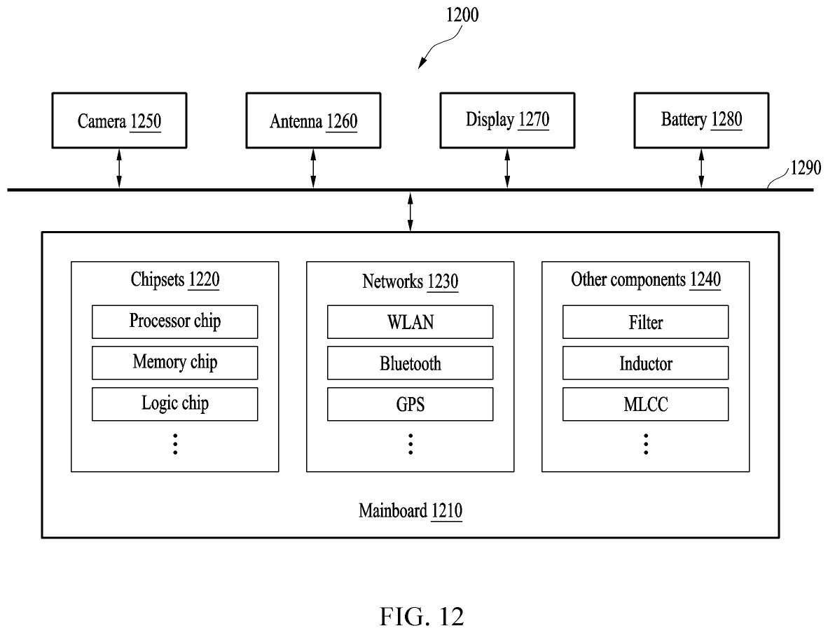

FIG. 12 is a diagram illustrating a configuration of an electronic device system including a semiconductor package according to some embodiments of the present disclosure.

Referring to FIG. 12, an electronic device 1200 may accommodate a mainboard 1210. Chipsets 1220, networks 1230, and other components 1240 may be physically and/or electrically connected to the mainboard 1210. These components may be combined with other electronic components described later to form multiple signal lines 1290.

The chipsets 1220 may include a memory chip (e.g., volatile memory, non-volatile memory or flash memory), an application processor chip (e.g., a central processor, a graphics processor, a digital signal processor, a cryptographic processor, a microprocessor or a microcontroller), and a logic chip (e.g., an analog-to-digital converter or an application-specific integrated circuit (ASIC)). In addition, other types of chip-related electronic components may be included. Additionally, these chipsets 1220 may be combined with each other.

The networks 1230 may include wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. In addition, any other wireless or wired standards or protocols may be included. Additionally, the networks 1230 may be combined with each other, together with the chipsets 1220.

The other components 1240 may include a high frequency inductor, a ferrite inductor, a power inductor, ferrite beads, a low temperature co-fired ceramic (LTCC), an electromagnetic interference (EMI) filter, a multilayer ceramic capacitor (MLCC), and the like. In addition, passive components used for various other purposes may be included. Additionally, the other components 1240 may be combined with each other, together with the chipsets 1220 and/or the networks 1230.

Depending on the type of the electronic device 1200, the electronic device 1200 may include other electronic components that may or may not be physically or electrically connected to the mainboard 1210. The other electronic components may include, for example, a camera 1250, an antenna 1260, a display 1270, a battery 1280, an audio codec, a video codec, a power amplifier, a compass, an accelerometer, a gyroscope, a speaker, a mass storage unit, a compact disk (CD), a digital versatile disk (DVD), and the like. In addition, electronic components used for various purposes may be included depending on the type of electronic device 1200.

The electronic device 1200 may be a smartphone, a personal digital assistant (PDA), a digital video camera, a digital still camera, a network system, a computer, a monitor, a tablet computer, a laptop computer, a netbook, a television, a video game machine, a smart watch, or the like. In addition, the electronic device 1200 may be any other electronic device that processes data.

The semiconductor package 1, the semiconductor package 2, and semiconductor package 3 according to some embodiments of the present disclosure described above with reference to the drawings may be applied to various electronic devices 1200 for various purposes.

A number of non-limiting example embodiments of the present disclosure have been described above. Nevertheless, it should be understood that various modifications and variations may be made to these example embodiments. For example, embodiments of the present disclosure may be achieved if the described techniques are performed in a different order, and/or if components in a described system, architecture, device, or circuit are combined in a different manner, and/or replaced or supplemented by other components or their equivalents.

Therefore, other implementations, other embodiments, and/or equivalents are within the scope of the present disclosure.

What is claimed is:

1. A semiconductor package comprising:
a substrate structure comprising:
an inner substrate pad contacting a surface-mount semiconductor chip; and
an outer substrate pad on an outer side of the inner substrate pad;
a dam structure between the inner substrate pad and the outer substrate pad; and
an underfill material layer comprising an underfill material filling an inside of the dam structure,
wherein the dam structure comprises:
a plurality of dambars configured to reduce leakage of the underfill material in a direction from the inner substrate pad to the outer substrate pad;
a plurality of connecting pads connecting the plurality of dambars to each other;
a plurality of fixing pads in the substrate structure; and
a plurality of fixing vias connecting the plurality of fixing pads and the plurality of connecting pads, respectively, and
wherein a width of each dambar among the plurality of dambars is smaller than a width of each of a pair of fixing pads, among the plurality of fixing pads, closest to a corresponding dambar among the plurality of dambars.

2. The semiconductor package of claim 1, wherein the plurality of dambars are spaced apart from the plurality of fixing vias and indirectly connected to the plurality of fixing vias by the plurality of connecting pads.

3. The semiconductor package of claim 2, wherein the surface-mount semiconductor chip comprises an inner connection terminal in a shape of a solder bump that contacts the inner substrate pad, and
wherein the substrate structure further comprises a protective layer that comprises:
a protective layer insulator comprising a solid-state interlayer insulating film; and
a protective layer via that at least partially penetrates the protective layer insulator such as to be electrically connected to the outer substrate pad or the inner substrate pad, and
wherein the protective layer is an outermost layer of the substrate structure.

4. The semiconductor package of claim 2, wherein the substrate structure further comprises a protective layer that comprises:
a protective layer insulator comprising an insulating material; and
a protective layer via that at least partially penetrates the protective layer insulator such as to be electrically connected to the outer substrate pad or the inner substrate pad,
wherein the protective layer is an outermost layer of the substrate structure,
wherein the outer substrate pad and the inner substrate pad protrude from the protective layer insulator, and
wherein the plurality of dambars, the plurality of connecting pads, the outer substrate pad, and the inner substrate pad each have a same protruding height from the protective layer insulator.

5. The semiconductor package of claim 4, wherein the substrate structure further comprises a first redistribution layer that comprises:
a first redistribution insulator that comprises an insulating material;
a first redistribution pad that is electrically connected to the protective layer via, protrudes from the first redistribution insulator, and is within the protective layer insulator; and
a first redistribution via that at least partially penetrates the first redistribution insulator such as to be electrically connected to the first redistribution pad,
wherein the plurality of fixing pads are spaced apart from the first redistribution via, and
wherein the first redistribution pad and the plurality of fixing pads each have a same protruding height from the first redistribution insulator.

6. The semiconductor package of claim 5, wherein the semiconductor package further comprises an additional semiconductor chip,
wherein the protective layer is between the additional semiconductor chip and the surface-mount semiconductor chip, and
wherein the additional semiconductor chip is electrically connected to the inner substrate pad and the outer substrate pad by the first redistribution via, the first redistribution pad, and the protective layer via.

7. The semiconductor package of claim 6, wherein the substrate structure further comprises:
a core substrate comprising:
a core insulator that comprises a chip accommodation space in which the additional semiconductor chip is accommodated; and
a core wiring pattern that at least partially penetrates the core insulator such as to be electrically connected to the first redistribution layer; and
a second redistribution layer comprising:
a second redistribution insulator that comprises an insulating material;
a second redistribution via that at least partially penetrates the second redistribution insulator such as to be electrically connected to the core wiring pattern; and
a second redistribution pad that is electrically connected to the second redistribution via and exposed to an outside of the second redistribution insulator, and
wherein the semiconductor package further comprises a molding layer that comprises an insulating material and fills a space between the core insulator and the additional semiconductor chip.

8. The semiconductor package of claim 1, wherein the dam structure has a closed loop shape in which the inner substrate pad is surrounded by the plurality of dambars and the plurality of connecting pads,
wherein the plurality of connecting pads are at corner portions of the closed loop shape,
wherein the plurality of dambars are on straight portions of the closed loop shape, and
wherein the width of each dambar among the plurality of dambars is smaller than a width of each of a pair of connecting pads, among the plurality of connecting pads, directly connected to a corresponding dambar among the plurality of dambars.

9. The semiconductor package of claim 8, wherein the closed loop shape is a rectangular shape, and
wherein the plurality of connecting pads are at vertices of the rectangular shape, respectively.

10. The semiconductor package of claim 1, wherein the plurality of dambars comprise:
a dispensing-side bar having a longest shortest distance, among the plurality of dambars, from the inner substrate pad; and
an exit-side bar on a side of the inner substrate pad that faces away from the dispensing-side bar;
wherein an area surrounded by the dam structure comprises:
a dispensing area that is a space between the inner substrate pad and the dispensing-side bar; and
an exit area that is a space between the inner substrate pad and the exit-side bar, and
wherein a width of the dispensing area is greater than a width of the exit area.

11. The semiconductor package of claim 10, wherein a shortest distance from each of a pair of connecting pads, that are among the plurality of connecting pads and directly connected to the dispensing-side bar, to the inner substrate pad is longer than a shortest distance from the dispensing-side bar to the inner substrate pad.

12. The semiconductor package of claim 1, wherein a shortest distance from each connecting pad, among the plurality of connecting pads, to the inner substrate pad is longer than a shortest distance from each of a pair of dambars, that are among the plurality of dambars and directly connected to a corresponding connecting pad among the plurality of connecting pads, to the inner substrate pad.

13. The semiconductor package of claim 1, wherein a width of one fixing via among the plurality of fixing vias is smaller than a width of a fixing pad directly connected to the one fixing via among the plurality of fixing vias,
wherein a width of a connecting pad, among the plurality of connecting pads, directly connected to the one fixing via is greater than the width of the one fixing via, and
wherein a width of a dambar, that is among the plurality of dambars and closest to the one fixing via, is smaller than the width of the connecting pad directly connected to the one fixing via and the width of the fixing pad directly connected to the one fixing via.

14. The semiconductor package of claim 1, wherein the width of each dambar among the plurality of dambars is equal to or smaller than ½ of the width of each of the pair of fixing pads, among the plurality of fixing pads, closest to a corresponding dambar among the plurality of dambars.

15. The semiconductor package of claim 5, wherein the first redistribution layer further comprises a first redistribution line that is electrically connected to the first redistribution via or the first redistribution pad, protrudes from the first redistribution insulator, and is within the protective layer insulator, and
wherein when viewed in a direction parallel to a depth direction of the first redistribution via, the first redistribution line comprises a shape that traverses at least a portion of the plurality of dambars, and is electrically connected to the outer substrate pad.

16. A method of manufacturing a semiconductor package, the method comprising:
forming an intermediate semiconductor package;
forming, in the intermediate semiconductor package, a substrate structure including a dam structure, an inner substrate pad inside the dam structure, and an outer substrate pad outside of the dam structure;
bonding a surface-mount semiconductor chip to the inner substrate pad; and
filling an inside of the dam structure with an underfill material,
wherein the dam structure comprises:
a plurality of dambars configured to reduce leakage of the underfill material to the outer substrate pad;
a plurality of connecting pads connecting the plurality of dambars to each other;
a plurality of fixing pads in the substrate structure; and
a plurality of fixing vias connecting the plurality of fixing pads and the plurality of connecting pads, respectively, to each other, and
wherein a width of each dambar among the plurality of dambars is smaller than a width of each of a pair of fixing pads, among the plurality of fixing pads, closest to a corresponding dambar among the plurality of dambars.

17. The method of claim 16, wherein the forming the substrate structure comprises forming a first redistribution layer in the intermediate semiconductor package and separating the plurality of fixing pads from a wiring pattern of the substrate structure,
wherein the forming the first redistribution layer comprises:
forming a first redistribution insulator including a hole to form a first redistribution via;
depositing a first redistribution metal film on the first redistribution insulator;
disposing, on the first redistribution metal film, a first redistribution mask that includes (i) a hole to form a first redistribution pad electrically connected to the first redistribution via and (ii) holes to form the plurality of fixing pads; and
forming, by a first plating process, the first redistribution via, the first redistribution pad, and the plurality of fixing pads simultaneously by plating the first redistribution metal film in a state in which the first redistribution mask is disposed, and
wherein the separating the plurality of fixing pads from the wiring pattern of the substrate structure comprises etching the first redistribution metal film after the first plating process is performed.

18. The method of claim 17, wherein the forming the substrate structure further comprises forming a protective layer on the first redistribution layer and separating the dam structure from the wiring pattern of the substrate structure,
wherein the forming the protective layer comprises:
forming a protective layer insulator that includes (i) a hole to form a protective layer via electrically connected to the first redistribution pad and (ii) holes to form the plurality of fixing vias;
depositing a protective layer metal film on the protective layer insulator;
disposing, on the protective layer metal film, a protective layer mask that includes (i) a hole to form the outer substrate pad, (ii) a hole to form the inner substrate pad, (iii) holes to form the plurality of dambars, and (iv) holes to form the plurality of connecting pads; and
forming, by a second plating process, the protective layer via, the plurality of fixing vias, the outer substrate pad, the inner substrate pad, the plurality of dambars, and the plurality of connecting pads simultaneously by plating the protective layer metal film in a state in which the protective layer mask is disposed, and
wherein the separating the dam structure from the wiring pattern of the substrate structure comprises etching the protective layer metal film after the second plating process is performed.

19. The method of claim 18, wherein the forming the intermediate semiconductor package comprises:
forming a core substrate that includes a core insulator that includes a chip accommodation space to accommodate an additional semiconductor chip, and a core wiring pattern that at least partially penetrates the core insulator such as to be electrically connected to the first redistribution layer;
disposing the additional semiconductor chip in the chip accommodation space; and
forming a molding layer by filling a space between the core insulator and the additional semiconductor chip.

20. The method of claim 19, wherein the forming the substrate structure further comprises forming a second redistribution layer on a side of the first redistribution layer on which the additional semiconductor chip is provided,
the forming the second redistribution layer comprises:
forming a temporary protective layer on surfaces of the protective layer metal film, the outer substrate pad, the inner substrate pad, and the dam structure;
forming a second redistribution insulator on a side of the temporary protective layer, and a second redistribution pattern that at least partially penetrates the second redistribution insulator to be electrically connected to the core wiring pattern, in a state in which a carrier is attached to the temporary protective layer; and
removing the temporary protective layer such that the surfaces of the protective layer metal film, the outer substrate pad, the inner substrate pad, and the dam structure are exposed to an outside, and
wherein the separating the dam structure from the wiring pattern of the substrate structure is performed after the forming the second redistribution layer.
